(19) United States
(12) Patent Application Publication
(10) Pub. No.: US 2008/0157753 A1
(43) Pub. Date: Jul. 3, 2008

(54) SYSTEM AND METHOD FOR DETERMINING THE PERFORMANCE OF AN ON-CHIP INTERCONNECTION NETWORK

(76) Inventors: Philippe Boucard, Le Chesnay (FR); Alain Fawaz, Guyancourt (FR)

Correspondence Address: MEYERTONS, HOOD, KIVLIN, KOWERT & GOETZEL, P.C., P.O. BOX 398, AUSTIN, TX, 78767-0398, US

(21) Appl. No.: 11/749,908

(22) Filed: May 17, 2007

(30) Foreign Application Priority Data
Dec. 27, 2006 (FR) FR 0655979

(51) Int. Cl. G01R 1/06

(52) U.S. Cl. 324/149

(57) ABSTRACT

This system for determining the performance of an interconnection network of functional blocks of a specialized integrated circuit, comprises a set of probing modules disposed on the network and comprising means for detecting an event on at least one communication link of the network and means for determining a characteristic indicative of the activity of the said at least one link on the basis of the detection of the said event.

### BACKGROUND OF THE INVENTION

1. Field of the Invention

The invention relates to specialized integrated circuits and, more particularly, to the detection of the performance of an interconnection network of specialized integrated circuits.

2. Description of the Relevant Art Network on-chip (“NoC”) integrated circuits include a set of functional blocks each ensuring the execution of one or more elementary functions integrated on the circuit and interlinked by an interconnection network, generally designated by the term “On-chip Interconnect Network”.

The interconnection network is thus responsible for making the functional blocks communicate even when they are integrated in different clock domains of the integrated circuit or when they use different protocols, by virtue of a common message transport protocol.

During design, it is necessary to estimate the communication requirements of the interconnection network between the various functional blocks so as to define a network architecture having the best compromise between high performance and low cost, and which meets these communication requirements. This estimation is generally performed by constructing traffic models for each functional block. Models which are closer to the physical implementation are constructed thereafter so as to simulate at each clock cycle the behavior of the circuit as a function of the traffic representative of an application considered.

This validation, which consists in formulating a traffic model on the basis of an estimate of the communication requirements between the functional blocks, presents a certain number of drawbacks.

Firstly, it is limited by the simulation time which must necessarily remain reasonable. Furthermore, the behavior of the software implementing the application cannot always be easily modeled. Finally, another drawback is related to the limited speed of the tools used to implement the modeling of the traffic.

There therefore exists a requirement to have available a system for determining the performance of an interconnection network of functional blocks of an NoC circuit which can analyze in real time the performance of a circuit implementing a software application, of relatively low cost and which does not disturb the performance and the proper operation of the NoC integrated circuit.

### SUMMARY OF THE INVENTION

In one embodiment, a system for determining the performance of an interconnection network of functional blocks of a specialized integrated circuit is described.

According to one embodiment, a system includes a set of probing modules disposed on the network and including at least one probing unit including means for detecting an event on at least one communication link of the network and means for determining a characteristic indicative of the activity of the said at least one link on the basis of the detection of the said event.

Thus, by simply providing probing modules on communication links, it is possible to ensure the detection of predetermined events which then serve to determine the performance of the monitored network.

For example, the parameter detected by the probing modules may include the bandwidth of the link monitored, the number of packets transmitted, and the size of the payload. However, any other parameter, indicative of the activity of the interconnection network, may also be monitored.

According to another embodiment, the means for determining the said characteristic includes counting means for counting the number of events detected.

The counting means may also be adapted for counting a number of clock cycles between two detected events.

According to another embodiment, the probing modules are disposed in the form of a chain of ordered modules, messages for controlling the operation of the system being transmitted to the probing units in the form of frames of words whose position, in the frame, corresponds to the position, in the chain, of the said probing unit for which each word is intended.

Thus, for example, each probing module includes a counter for counting down the words successively received so as to determine the addressee of the said words.

Preferably, each probing module includes decoding means for decoding a first word of the frame indicating the type of information contained in the frame.

In an embodiment, the system furthermore includes a control module including global counters to which are transferred counting values of the counting means.

Preferably, the control module includes one or more configuration registers serving to indicate the chain of modules and the position, in the said chain, of the probing module from which the counting values originate.

In an embodiment, each probing unit includes a configuration register driving a selector for the selection of a communication link from among a plurality of links to which it is hooked up and the selection of a detected event, and a detection module ensuring the detection on the said link of the selected event.

Advantageously, the probing units are each provided on an interface of a functional block of the specialized integrated circuit.

Furthermore, when the probing modules are disposed in parts of the network that are regulated according to different clocks, the probing modules include asynchronous storage means of FIFO type ensuring an adaptation of the streams of data conveyed between the network parts.

In an embodiment, the probing modules include means for marking the packets of data conveyed between a functional block initiating a message to a target block and between a target block and an initiating block.

The system may furthermore include means for detecting latency on the basis of a detection of marked packets of words conveyed on a request link between an initiating block and a target block and of a detection of marked packets sent, in return, on a response link between the said target block and the said initiating block.

For example, the latency detection means includes a first probing unit for a module, including counting means which are dedicated to the counting of clock cycles and which are started after detection of a marked packet in a frame sent by the initiating block to the target block and which are stopped after detection of a marked packet in a frame received by the initiating block originating from the target block and a second probing unit for the said module, dedicated to the counting of marked packets transmitted.

In an embodiment, the system furthermore includes means for transferring the counting value of the global counters to an external memory, and triggering means for controlling the transfer of the said counting value.

In another embodiment, a method for determining the performance of an interconnection network of functional blocks of a specialized integrated circuit, includes:

detecting an event on at least one communication link of the interconnection network; and

formulating a characteristic indicative of the activity of the said at least one link on the basis of the detection of the said event.

Within the framework of the formulation of the characteristic indicative of the activity of the link, it is possible to count the number of events detected.

It is also possible to count a number of clock cycles between two events detected.

Prior to the detection of the events, a set of probing modules which are disposed on communication links of the network in the form of a chain of ordered modules and including at least one probing unit is configured by means of messages, for controlling the operation of the system, transmitted to the said units in the form of frames of words whose position, in each frame, corresponds to the position of a probing unit in the chain for which the word is intended, and whose width corresponds to the width of the communication links.

According to another embodiment of this method, a first coding word for the type of information contained in the message is sent in the control messages.

According to another embodiment, during an exchange of information between an initiating functional block and a target functional block, data packets sent by the initiating block to the target block are marked, data packets sent in response by the target block to the initiating block are marked, the number of clock cycles between the sending of the marked packets by the initiating block and the receiving of the marked packets sent by the target block is counted, and the number of marked packets transmitted and the number of clock cycles for transmitting each of them is counted.

It is moreover possible to transfer counting values resulting from the counting of the events detected and/or the number of clock cycles to global counters.

For example, successive values arising from one or more probing units are accumulated, a fixed configurable quantity is deducted from every clock cycle regulating a control means and the transfer of the data is brought about when the accumulated value exceeds a configurable threshold value.

It is also possible to accumulate successive values arising from a first probing unit, a fixed configurable quantity is deducted a number of times equal to a value arising from a second probing unit and a signal for triggering the transfer is generated when the accumulated value exceeds a configurable predetermined threshold value.

### BRIEF DESCRIPTION OF THE DRAWINGS

Other aims, characteristics and advantages of the invention will appear on reading the following description, given merely by way of non-limiting example, and offered with reference to the appended drawings, in which

FIG. 1 illustrates the general architecture of a system for determining the performance of an interconnection network of an NoC circuit in accordance with the invention;

FIG. 2 illustrates the general architecture of a probing module used in the system of FIG. 1; and

FIG. 3 illustrates the transfer of the data between the probing modules when they are situated in different clock domains.

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

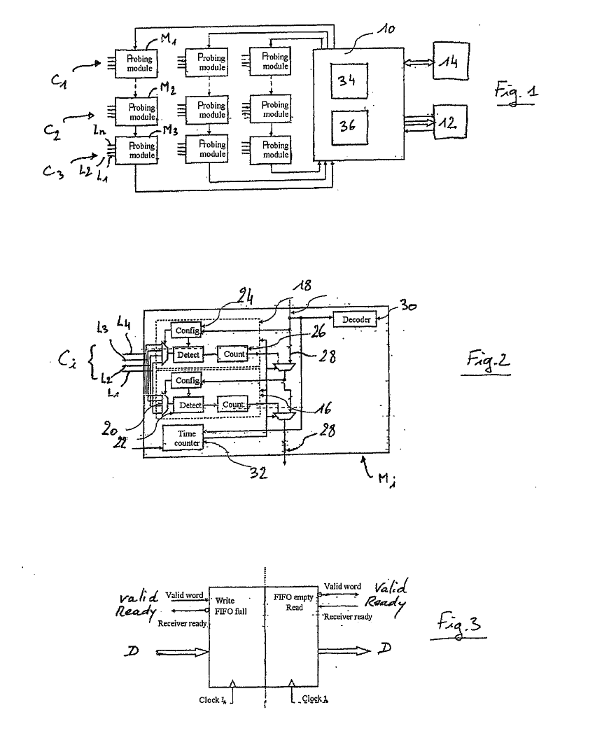

Represented in FIG. 1 is the general architecture of a system for measuring the performance of an interconnection network of functional blocks of an NoC specialized integrated circuit. This system is intended to be integrated with the interconnection network of the circuit, and, in particular, to be disposed on communication channels, such as C1, C2 and C3, so as to monitor the traffic of data conveyed on these channels and thus determine the activity and the performance of the NoC circuit.

In particular, the system illustrated is intended to detect operating parameters of the network on one or more communication links L1, L2 . . . , LN of each channel between functional blocks using for example different communication protocols and having different clock frequencies.

As may be seen, the system includes for this purpose a set of probing modules, such as M1, M2 and M3 hooked up to a control module 10 ensuring the configuration of the probing modules M1, M2 and M3 and the recovery of the parameters detected by these modules. Each probing module is placed on a communication channel and monitors the links L1, L2 . . . LN of this channel in parallel, namely the request links, on which there flow requests transmitted by an initiating functional block, on the initiative of which is instigated a transfer of data, to a target functional block and response links, on which there flow responses transmitted by a target functional block, to an initiating functional block in response to a request. However, it would also be possible to provide, as a variant, a probing module ensuring the monitoring of the request links from the initiating block to the target block and a separate probing module ensuring the monitoring of the request links from the target block to the initiating block.

It will however be noted that, preferably, the probing modules are positioned at the interfaces of the network of the traffic initiating or target functional blocks.

As will be described in detail subsequently, each probing module includes one or more probing units 16, 18, here two in number, ensuring the detection of the parameters to be extracted from the links.

The control module 10 ensures the configuration of the probing units in the probing modules so as, on the one hand, to select one or more links to be observed and, on the other hand, to select the parameter to be detected, for example the bandwidth, the number of packets flowing over the link, the size of the useful data of each packet transmitted, etc. The control module 10 also ensures the collection of the information arising from the probing modules and is hooked up to a parallel downloading interface 12, for example of DDR (“Double Data Rate”) type for the transferring of the performance information out of the system. It is also hooked up to a serial configuration interface 14, for example of JTAG type, making it possible, by programming, to configure the control means from outside with the goal of choosing the type of events to be observed on the communication links and to selecting one or more communication links to be observed.

The structure of each probing module will now be described with reference to FIG. 2.

As indicated previously, each probing module Mi includes one or more probing units 16 and 18, here two in number, ensuring the detection of the parameters to be extracted from the links.

Each probing unit 16 or 18 includes a selector 20 hooked up, at input, to the links L1, L2, L3 and L4 of a communication channel Ci, here four in number, so as to ensure the selection of one of the links to which it is hooked up with a view to its observation.

It furthermore includes a detection module 22 hooked up to the selector 20 so as to receive the data conveyed by the selected link and to detect the characteristic or characteristics to be monitored. A configuration register 24 is used to configure the selector 20 and the detection module 22 so as, on the one hand, to select one of the links to be observed and, on the other hand, to select the parameter to be monitored. A counter 26 hooked up to the detection module ensures moreover the counting of the parameters detected.

Among the possible events liable to be detected by the detection module 22 will be the detection of packets, the number of useful data associated with each packet, the detection of the state of the link: transfer in progress (valid data present), occupied (receiver not ready), on standby (no valid data possible), the quantity of transfer, of links occupied or of links on standby, of gaps in the packets (invalid data in a packet), of priority or non-priority messages, of types of messages (write, read), of marking of certain packets dedicated to the measurement of latency, etc.

When one wishes to measure a number of clock cycles, the detection module 22 outputs a “1” permanent logic level so that a detection of events is available at each clock cycle. This makes it possible to establish all kinds of statistics making it possible to characterize the quality of operation of the observed network. After detection, the events or parameter observed are counted by the counter 26, the results of the counter being transferred thereafter to the control module 10.

It will be noted that all the probing units 16 and 18 are hooked up in the form of an ordered chain forming a loop so that access to the probing units is performed sequentially and not by addressing. They are connected by links, such as 28, which include a relatively small number of wires, for example eight in number, so as to decrease the information transport cost. These links 28 are used at one and the same time to configure each unit, to read the configuration, to recover the value of the counters 26 or to start, stop and initialize the counters, in particular by action on the configuration registers 24, so that the size of these registers 24 or the maximum size of the counters is limited to the width of the links in the loops of probing units 16, 18.

Each probing module Mi furthermore includes a decoder 30 serving in particular to decode information flowing over the links 28 of each loop connecting the probing units 16, 18.

The information flowing in the loops actually takes the form of frames of messages consisting of words, whose number of bits corresponds to the number of wires of each link 28. Thus, for example, each word of a frame of words includes 8 bits. The first word is a code, intended to be decoded by the decoder 30, which indicates the type of information contained in the message.

The following words refer respectively to the probing units which have the same respective place in the chain as the words in the frame. Thus, for example, if dealing with a message for reading the counters 26, the second word of the frame of the message flowing in the loops corresponds to the value of the counter 26 of the first decoding unit 16 in the loop. If dealing with a configuration message, the following words contain the configurations of each of the configuration registers 24. As the configuration means 14 are generally slow of access and not often used, there can be as many configuration messages as probing units in the chain. A selection code reserved for masking the probing units which do not have to be configured is then advantageously used in each frame.

Thus, by virtue of the sequential access of the probing units in the loops, the words each intended for a probing unit are those which have the same position in the frame as the probing unit in the loop to which it belongs.

Each probing module Mi is moreover provided with a time counter 32 which ensures the counting of the valid words which flow in the probing units through the links 28, thereby making it possible to select the frame word associated with each register or counter of each probing unit in a probing module Mi. This counter 32 is initialized at the outset and is configured according to the number of probing units in the loop. It is initialized as soon as it has counted a number of valid words corresponding to the number of probing units in the loop plus one.

In the case of a transfer of information between a probing unit and the control means 10 (FIG. 1), after reading of the counters 26 of the probing units, these counters are immediately reinitialized. Likewise, on start-up, these counters are initialized to “0”.

It will also be noted that supplementary signals are transmitted on the links 28 of each loop, in addition to the data wires, so as, in particular, to better control the stream of messages.

Thus, for example, two additional signals are used, the first “valid” indicating that the sender of the message is currently dispatching a valid word, the second “ready”, the information of which flows in the opposite direction relative to the other wires of the link, indicating that the receiver of the message is ready to receive a new word. This makes it possible to employ loops which cross several different clock domains provided that a queue of FIFO asynchronous memory type with two clocks is inserted at each change of clock domain.

FIG. 3 shows an asynchronous FIFO-type queue with two clocks, which is used to go from a clock domain of a clock 1 to another clock domain of a clock 2. In the left domain of FIG. 3 (clock 1), as long as the FIFO memory is not full, the FIFO is ready to receive. It is therefore possible to write valid data D. The valid word signal “valid” thus serves as write command and the signal indicating that the FIFO memory is not full serves as “ready” signal for the incoming link 28.

In the right domain (clock 2), as long as the receiver is ready, it is possible to read new data. A “ready” signal is thus sent. The receiver ready signal “ready” therefore serves as read command. If there are data D to be read (FIFO not empty) then these data are valid and the signal indicating that the FIFO memory is not empty therefore serves as “valid” signal for the outgoing link 28. The optimum number of words in the FIFO memory depends on the ratio of the frequencies of the two clocks. It will however be noted that it has been found that 5 or 6 words generally suffice. It is therefore possible to chain together units in different clock domains. However, one will seek to minimize the number of changes of domain so as to keep the lowest possible costs. The most commonplace is to dispose the control module 10 on a clock domain which may be different from the clock domain of certain of the probing modules Mi. In this case, the asynchronous FIFO memory will be found at the start and at the end of the loop connecting these probing modules.

The counting data extracted from the counters 26 of each probing unit 16, 18 are used, by the control means 10, to formulate a characteristic which is indicative of the activity of each link monitored.

For example, this information is used to measure latencies in the interconnection network of functional blocks. A device for marking the packets which is supported by the transport protocol of the network is then used, moreover. This protocol allows the tagging of a packet of requests sent by a functional block initiating a transaction up to a target block and this tagging is transmitted by the target block in the associated response packet sent in return back to the initiating block. After having marked a packet, the time elapsed between its departure from the initiator and the return of the associated response packet is measured.

A measurement of latency may be undertaken using two coupled probing units.

Each probing unit detects an event, the first detects the passage of a marked packet over the requests link and the second the passage of a marked packet over the responses link. It should be noted that the network marks the packets in such a way that there is just one marked packet at a time on the links under observation. The first unit counts the clock cycles by starting at each of the events that it detects and stops on each of the events detected by the second unit. This involves a measurement over several transfers of marked packets. The second counts the packets marked and, consequently, counts the events of the two units.

As indicated previously, the latency measurement uses two probing units at a time of one and the same probing module. The first serves to accumulate the clock cycles on the basis of the passage of a marked packet over any one of the request links from an initiator, until the arrival of the associated response packet, marked by the target block, on one of the response links of this initiator. The second unit serves to count the number of marked packets received on one of the response links of this same initiator.

The counters of the two probing units ensure, one, a counting of clock cycles and, the other, a counting of the packets marked on the basis of these events.

Thus, during a transfer of information between a probing unit and the control means 10, we transfer the number of cycles accumulated and the number of corresponding packets, to within half a packet. The control means 10 are then able to formulate a latency characteristic by calculating the ratio between, on the one hand, the total accumulated number of clock cycles during the transfer of the marked packets, and on the other hand, the number of marked packets conveyed in the course of the said clock cycles, accurate to within half an integer.

As indicated previously, the control means 10 are intended to gather the information detected by the probing units 16, 18, of each probing module Mi.

For this purpose they includes global counters, such as 34, of larger capacity than that of the counters 26 of the probing units. These counters 34 are associated with one or two configuration registers 36 so as to indicate, for each global counter 34, the loop and the probing units from which the information should be recovered. The positions which correspond to the positions and to the loops configured in the configuration registers 36 associated with each of the global registers are tagged in the packets that flow around the links 28 of the loops, by virtue of the sequential access of the probing units, so as to accumulate the information in said global registers. It will however be noted that only a few probing units are under observation at a time so as to limit costs. One will also limit oneself to the case where the units observed are consecutive, thereby making it possible to specify the whole set of units by indicating just the first and the last.

The results of the global counters may be used to constitute a trace of the performance of the interconnection network. As indicated previously, to do this, use is made of a parallel interface 12 for communication with the outside (FIG. 1). It will be noted that the data are generally transferred to an external clock domain, so that an asynchronous memory of FIFO type with two clocks will be used, such as described previously in order to adapt the information stream.

As the external memory is of finite size, once it has been filled, the oldest data are overwritten by the new ones. The results are then utilized by stopping storage under the control of triggering means (not represented) which, just like the global counters, observe elements originating from one or more probing units. Storage may be stopped either to view the trace recorded before triggering so as to analyze the conditions leading to the said triggering, or just after triggering so as to analyze the behavior of the system after the trigger event.

For example, the triggering means include a measurement device for measuring a pseudo-throughput of events over a given period. An events count is accumulated in the device on the basis of the messages received from the probing units and, at each cycle of the clock regulating the control means 10, a configurable fixed quantity is deducted. When the quantity thus accumulated exceeds a threshold, the value of this threshold being itself configurable, this triggers the stopping of the storage of the trace. Thus, what triggers the device is a number of given events over a sliding window of determined duration.

When the trigger event is a latency, in so far as the determination of the latency implements two counts, use is made of a first count of clock cycles, counted as a cycle of the clock local to the probing unit, and a second count which is a count of marked packets. The triggering device will then accumulate the clock cycles and subtract a fixed quantity a number of times equal to the number of packets metered, that is to say a fixed configurable quantity is deducted and simultaneously the packet count is decremented so long as the packet count is not zero. One thus monitors that the latency cycles lost do not exceed a given value over a sliding window of a determined duration.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. System for determining the performance of an interconnection network of functional blocks of a specialized integrated circuit, comprising a set of probing modules disposed on the network and comprising at least one probing unit comprising means for detecting an event on at least one communication link of the network and means for determining a characteristic indicative of the activity of the said at least one link on the basis of the detection of the said event.

2. System according to claim 1, wherein the means for determining the said characteristic comprise counting means for counting the number of events detected.

3. System according to claim 1, wherein the means for determining the said characteristic comprises counting means for counting a number of clock cycles between two detected events.

4. System according to claim 1, wherein the probing modules are disposed in the form of a chain of ordered modules and in that messages for controlling the operation of the system are transmitted to the probing units in the form of frames of words whose position, in the frame, corresponds to the position, in the chain, of the said probing unit for which each word is intended.

5. System according to claim 4, wherein each probing module comprises a counter for counting down the words successively received so as to determine the addressee of the said words.

6. System according to claim 4, wherein each probing module comprises decoding means for decoding a first word of the frame indicating the type of information contained in the frame.

7. System according to claim 1, further comprising a control module comprising global counters to which are transferred counting values of the counting means.

8. System according to claim 7, wherein the control module comprises one or more configuration registers serving to indicate the chain of modules and the position, in the said chain, of the probing module from which the counting values originate.

9. System according to claim 1, wherein each probing unit comprises a configuration register driving a selector for the selection of a communication link from among a plurality of links to which it is hooked up and the selection of a detected event, and a detection module ensuring the detection on the said link of the selected event.

10. System according to claim 1, wherein the probing units are each provided on an interface of a functional block of the specialized integrated circuit.

11. System according to claim 1, wherein the probing modules are disposed in parts of the network that are regulated according to different clocks, wherein the system further comprises asynchronous storage means of FIFO type ensuring an adaptation of the streams of data conveyed between the network parts.

12. System according to claim 1, further comprising means for marking the packets of data conveyed between a functional block initiating a message to a target block and between a target block and an initiating block.

13. System according to claim 12, further comprising means for detecting latency on the basis of a detection of market packets of words conveyed on a request link between an initiating block and a target block and of a detection of marked packets, in return, on a response link between the said target block and the said initiating block.

14. System according to claim 13, wherein the latency detection means comprise a first probing unit for a detection module, comprising counting means which are dedicated to the counting of clock cycles and which are started after detection of a marked packet in a frame sent by the initiating block to the target block and which are stopped after detection of a marked packet in a frame received by the initiating block originating from the target block and a second probing unit for the said module, dedicated to the counting of marked packets transmitted.

15. System according to claim 7, further comprising means for transferring part at least of the counting value of the global counters to an external memory, and triggering means for controlling the transfer of the said counting value.

16. Method for determining the performance of an interconnection network of functional blocks of a specialized integrated circuit, comprising:
detecting an event on at least one communication link of the interconnection network; and
determining a characteristic indicative of the activity of the said at least one link on the basis of the detection of the said event.

17. Method according to claim 16, wherein the number of events detected is counted.

18. Method according to claim 16, wherein a number of clock cycles between two detected events is counted.

19. Method according to claim 16, wherein prior to the detection of the events, a set of probing modules which are disposed on communication links of the network in the form of a chain of ordered modules and which comprise at least one probing unit is configured by means of messages, for controlling the operation of the system, transmitted to the said units in the form of frames of words whose position, in each frame, corresponds to the position of a probing unit in the chain for which the word is intended, and whose width corresponds to the width of the communication links.

20. Method according to claim 19, wherein a first coding word for the type of information contained in the message is sent in the control messages.

21. Method according to claim 16, wherein during an exchange of information between an initiating functional block and a target functional block, data packets sent by the initiating block to the target block are marked, data packets sent in response by the target block to the initiating block are marked, the number of clock cycles between the sending of the marked packets by the initiating block and the receiving of the marked packets sent by the target block is counted, and the number of marked packets transmitted is counted.

22. Method according to claim 17, wherein counting values resulting from the counting of the events detected and/or the number of clock cycles are transferred to global counters.

23. Method according to claim 22, wherein successive values arising from one or more probing units are accumulated, a fixed configurable quantity is deducted at every clock cycle regulating a control means and the transfer of the data is brought about when the accumulated value exceeds a configurable threshold value.

24. Method according to claim 22, wherein successive values arising from a first probing unit are accumulated, a fixed configurable quantity is deducted a number of times equal to a value arising from a second probing unit and a signal for triggering the transfer is generated when the accumulated value exceeds a configurable predetermined threshold value.
